(19) United States
(12) Patent Application Publication
(10) Pub. No.: US 2016/0269171 A1
(43) Pub. Date: Sep. 15, 2016

(54) RADIO COMMUNICATION DEVICE AND PLL LOOP CONTROL METHOD

(71) Applicant: KABUSHIKI KAISHA TOSHIBA, Tokyo (JP)

(72) Inventor: Hiroki SAKURAI, Ota Tokyo (JP)

(73) Assignee: KABUSHIKI KAISHA TOSHIBA, Tokyo (JP)

(21) Appl. No.: 14/844,977

(22) Filed: Sep. 3, 2015

(30) Foreign Application Priority Data
Mar. 13, 2015 (JP) 2015-051473

(51) Int. Cl. H04L 7/033; H03L 7/093; H03L 7/099; H03L 7/091

(52) U.S. Cl. CPC H04L 7/0331; H03L 7/091; H03L 7/093; H03L 7/0991

(57) ABSTRACT

According to one embodiment, a radio communication device includes PLL circuit that adjusts, based on control data, a frequency of an output signal to a target value, a holder that temporarily holds, when a hold instruction signal to hold the control data is input, a state of the control data and releases, when an unhold instruction signal to unhold the control data is input, a holding state of the control data, a control unit that outputs the hold instruction signal in a PLL lock state in which the frequency of the output signal reaches the target value, and outputs the unhold instruction signal after the hold instruction signal is output and before the frequency of the output signal deviates from the target value or a vicinity of the target value.

### CROSS-REFERENCE TO RELATED APPLICATIONS

This application is based upon and claims the benefit of priority from the prior Japanese Patent Application No. 2015-051473, filed on Mar. 13, 2015; the entire contents of which are incorporated herein by reference.

### FIELD

Embodiments described herein relate generally to a radio communication device and a PLL loop control method.

### BACKGROUND

Conventionally, a phase-locked loop (PLL) circuit has been developed to be applied to an extended specification of the Bluetooth (registered trademark) called a Bluetooth low energy (BLE). The BLE has a communication specification for ultra-low power and is required to reduce power consumption of a communication device. In order to satisfy the requirement, it is expected that an OPEN mode to open a PLL loop is actively used in a communication device and the like. Especially, an all digital phase-locked loop (ADPLL), in which most of all internal circuits are configured with digital circuits, has a higher affinity with the BLE using frequency modulation than an analog PLL circuit. Therefore, further development of the ADPLL is attracting attention.

### BRIEF DESCRIPTION OF THE DRAWINGS

FIG. 1 is a block diagram of a radio communication device illustrated as an example of an embodiment;

FIG. 2 is a block diagram of an ADPLL illustrated as an example of the embodiment;

FIG. 3 is a diagram of a passing frequency band in a digital low-pass filter illustrated as an example of the embodiment;

FIG. 4 is an operation flow chart of a control unit illustrated as an example of the embodiment;

FIG. 5 is a diagram of a frequency change of an output signal of a DCO illustrated as an example of the embodiment when a PLL loop is returned;

FIG. 6 is a block diagram of an ADPLL illustrated as an example of a modified example 1;

FIG. 7 is an operation flow chart of a control unit at transmission illustrated as an example of the modified example 1;

FIG. 8 is a block diagram of an ADPLL illustrated as an example of a modified example 2;

FIG. 9 is a timing chart of a power control of a detector and the like illustrated as an example of the modified example 2;

FIG. 10 is an operation flow chart of a control unit at transmission illustrated as an example of the modified example 2;

FIG. 11 is a block diagram of an ADPLL illustrated as an example of a modified example 3; and

FIG. 12 is an operation flow chart of a control unit at transmission illustrated as an example of the modified example 3.

### DETAILED DESCRIPTION

In general, according to one embodiment, a radio communication device comprises a digitally controlled oscillator, a phase-to-digital converter, an integrator, a subtractor, a digital low-pass filter, a digital amplifier, a first detector, a first timer, a switch restriction unit, and a control unit.

The digitally controlled oscillator adjusts, based on control data, a frequency of an output signal. The phase-to-digital converter converts a feedback signal which is a signal that the output signal of the digitally controlled oscillator is fed back, into first phase data and outputs the first phase data. The integrator integrates frequency setting data and outputs second phase data. The subtractor generates phase difference data obtained by subtracting the above first phase data from the above second phase data. The digital low-pass filter filters the phase difference data and outputs basic control data. The digital amplifier generates control data from the basic control data output from the digital low-pass filter, outputs the control data to the digitally controlled oscillator, and outputs, when a hold instruction signal to hold the above control data is input, the control data without changing a value until an unhold instruction signal to unhold the hold instruction is input.

Furthermore, the first detector detects, based on the feedback signal, a phase-locked loop (PLL) lock state in which a frequency of the output signal of the digitally controlled oscillator reaches a target value indicated in the frequency setting data. The first timer clocks an estimated time until just before a frequency of the output signal of the digitally controlled oscillator deviates from the target value or a vicinity of the target value. The switch control unit stops or resumes signal input to at least one digital input/output unit by a prior stage of the digital amplifier on a transmission path through which the frequency setting data or the feedback signal of the digitally controlled oscillator is transmitted. The control unit performs PLL loop OPEN control in which the control unit outputs the hold instruction signal to the digital amplifier and further stops the signal input to the digital input/output unit by the switch control unit when the first detector detects the PLL lock state, and performs PLL loop ON control in which the control unit resumes the stopped signal input by the switch control unit and further outputs the unhold instruction signal to the digital amplifier when the first timer completes clocking the estimated time.

Hereinafter, with reference to the attached drawings, a radio communication device and a PLL loop control method according to an embodiment will be described in detail. Note that, the present invention is not limited by the embodiment.

### EMBODIMENT

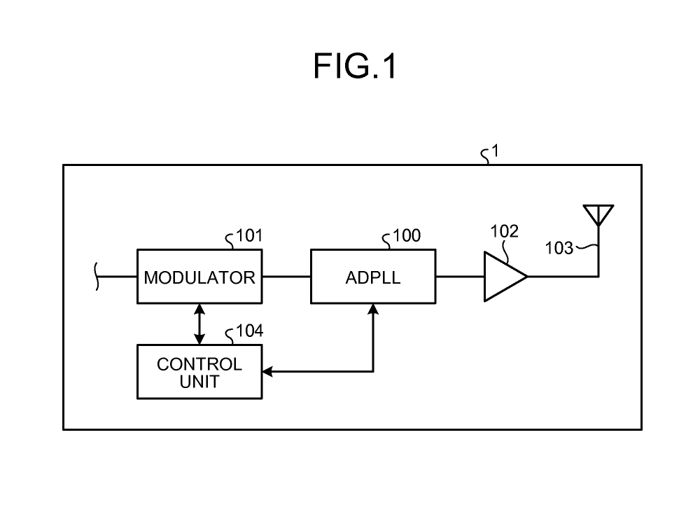

FIG. 1 is a block diagram of a radio communication device illustrated as an example of an embodiment.

As illustrated in FIG. 1, a radio communication device 1 includes, as a transmission processing unit, an all digital phase-locked loop (ADPLL) 100, a modulator 101, a power amplifier 102, an antenna 103, and a control unit 104. In addition, the radio communication device 1 includes a reception processing unit, which is not illustrated, and transmits/receives data at the reception processing unit or the transmission processing unit.

The ADPLL 100 is a PLL circuit that adjusts a frequency of an output signal based on a feedback signal of the output signal. The ADPLL 100 all digitally adjusts the frequency of the output signal.

The modulator 101 inputs, to the ADPLL 100, a baseband signal (modulation data) input from a data processing unit (not illustrated), such as a digital signal pocessor (DSP), and modulates the output signal of the ADPLL 100 according to a modulation technique, such as a gaussian filtered frequency shift keying (GFSK).

The power amplifier 102 is an amplifier that power-amplifies the signal output from the ADPLL 100. The antenna 103 is an antenna that radiates the signal power-amplified by the power amplifier 102. The control unit 104 is a control circuit that controls intermittent operation and the like of a PLL loop.

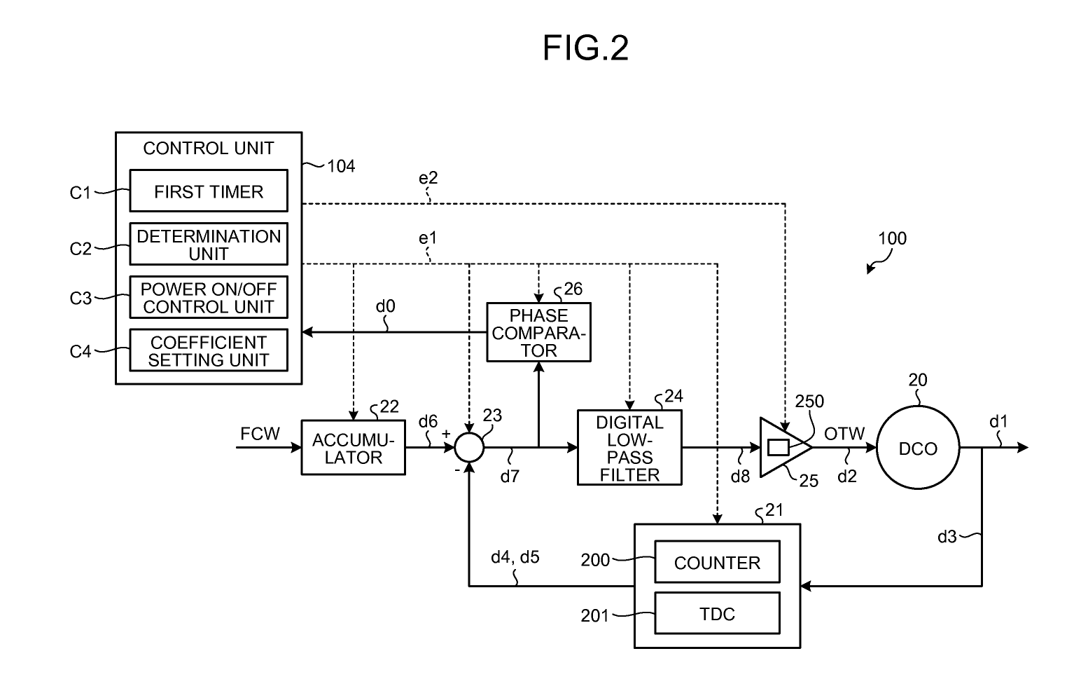

FIG. 2 is a block diagram of an ADPLL illustrated as an example of the embodiment.

The ADPLL 100 includes a DCO 20, a phase-to-digital converter 21, an accumulator 22, a subtractor 23, a digital low-pass filter 24, a digital amplifier 25, and a phase comparator 26. Each part of the ADPLL 100 is implemented by a digital circuit and operates according to a reference signal based on a crystal oscillator (not illustrated).

The DCO 20 is a digitally controlled oscillator that digitally controls and adjusts an oscillation frequency of the output signal. The DCO 20 has a number of MOS varactors (varicaps, variable capacity diodes, and the like) arranged in an array and changes the frequency by applying the corresponding control voltages of “0” or “1” to each of them and changing electrostatic capacitance digitally. As illustrated in FIG. 2, the DCO 20 inputs an oscillator tuning word (OTW) signal d2 from the digital amplifier 25, controls the electrostatic capacitance of the MOS varactor, and outputs a signal d1. Note that, it is assumed that the OTW signal d2 is a digital control data which consists of a plurality of bits individually indicating“0” or “1”.

The phase-to-digital converter 21 is a circuit that feeds back the signal d1 output from the DCO 20 and converts the signal (a feedback signal d3) into phase information (digital phase data) d4 and d5. This circuit is configured with a counter 200 and a time-to-digital converter (TDC) 201.

The counter 200 cumulatively integrates the frequency of the feedback signal d3 and outputs the phase information, which is the integrated result, to the subtractor 23 based on a timing signal. The TDC 201 extracts a phase difference between the two inputs of the reference signal and the feedback signal d3 with higher resolution and generates the phase information indicating a difference of a period or less of the feedback signal d3. The TDC 201 outputs the phase information to the subtractor 23 based on the reference signal.

The accumulator 22 is an integrator that integrates a frequency command word (FCW) indicating a set frequency and generates digital phase information. When the FCW is input, the accumulator 22 integrates the FCW and generates the phase information (digital phase data). The accumulator 22 outputs the phase information to the subtractor 23 based on the timing signal.

The subtractor 23 is a subtractor that extracts phase difference information. Phase information d6 from the accumulator 22 is input to an addition input terminal of the subtractor 23. A difference between the phase information d4 from the counter 200 and the phase information d5 of a period or less from the TDC 201 is input to a subtraction input terminal of the subtractor 23. The phase information d4 is an integer part and the phase information d5 is a fractional part. The subtractor 23 subtracts the phase information (d4 and d5) input to the subtraction input terminal from the phase information d6 input to the addition input terminal and generates phase difference information (digital phase difference data) d7.

The digital low-pass filter 24 performs filtering processing to high frequency components of the phase difference information d7 output from the subtractor 23 with a predetermined filter coefficient (coefficient) and outputs a control value (digital basic control data) d8 to the DCO 20 side. In addition, the digital low-pass filter 24 performs the filtering processing by dynamically changing the filter coefficient under intermittent operation control of the PLL loop by the control unit 104.

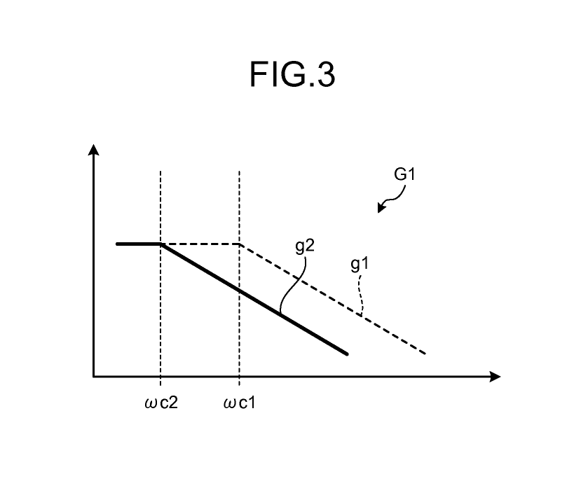

Here, the determination of the filter coefficient will be described with reference to FIG. 3.

FIG. 3 is a diagram schematically illustrating an example of a graph indicating each passing frequency band corresponding to each cutoff frequency in the digital low-pass filter 24 of the embodiment.

The graph G1 illustrates line graphs g1 and g2 which indicate a change of a pass rate to the frequency, when the abscissa indicates the frequency, and the ordinate indicates the pass rate.

The line graph g1 illustrates the change of the pass rate to the frequency, when the cutoff frequency is ωc1.

The line graph g2 illustrates the change of the pass rate to the frequency, when the cutoff frequency is ωc2.

Here, it is assumed that the relation is ωc2<ωc1.

The cutoff frequency ωc1 indicates the cutoff frequency applied to the digital low-pass filter 24 in the normal operation in which the PLL loop is closed.

As illustrated in FIG. 3, in the line graph g2, a higher frequency band (including the cutoff frequency ωc1) which passes in the line graph g1 is attenuated, and the pass rate of the frequency band decreases.

In accordance with this relation, at the timing when the PLL loop is closed again after once it is opened (when the PLL loop is returned), the cutoff frequency ωc2 is applied to the cutoff frequency of the digital low-pass filter 24. Thus, the signal of the high frequency band in the digital low-pass filter 24, which operates with the setting of the cutoff frequency ωc1 in the normal operation, is suppressed when the PLL loop is returned.

This becomes effective means for suppressing a sharp fluctuation of the frequency which appears in the output frequency of the DCO 20 caused by the passing of the high frequency band when the PLL loop is returned. Especially, in the BLE standard “LE Data Length Extension”, in order to satisfy the standard of the frequency deviation, it is preferable that a sharp fluctuation of the frequency, which appears in the output frequency of the DCO 20 when the PLL loop is returned, is suppressed. By applying the cutoff frequency ωc2 when the PLL loop is returned, the passing of the high frequency band is suppressed, and it is possible to satisfy the standard of the frequency deviation in the BLE standard “LE Data Length Extension”. Note that, in this case, the value of ωc2 satisfies the standard of the frequency deviation, and it is preferable that the value is an upper limit of the values.

In the following description, an example in which the cutoff frequency ωc2 is applied to the cutoff frequency of the digital low-pass filter 24 when the PLL loop is returned will be described. In this example, it is assumed that the cutoff frequency is returned to the cutoff frequency ωc1 for the normal operation after the PLL loop is locked, and the pass band is expanded.

More specifically, the digital low-pass filter 24 performs the filtering processing using the filter coefficient corresponding to the cutoff frequency ωc2 when the PLL loop is returned. The filtering processing is performed using the filter coefficient corresponding to the cutoff frequency ωc1 in the normal operation. The setting of the filter coefficient is performed, for example, by storing, in the control unit 104, the cutoff frequency ωc1, the cutoff frequency ωc2, or the value intermediate between them, calculated from the cutoff frequency in advance, and selectively setting the value to the digital low-pass filter 24 by the control unit 104 when the ADPLL 100 operates. Alternatively, the control unit 104 may calculate the value of the filter coefficient in accordance with a predetermined algorithm and set the calculated value to the digital low-pass filter 24 in each case.

Note that, the method that the control unit 104 returns the filter coefficient from the filter coefficient of the cutoff frequency ωc2 to the filter coefficient of the cutoff frequency ωc1 may be appropriately determined. For example, the filter coefficient of the cutoff frequency ωc2 may be returned to the filter coefficient of the cutoff frequency ωc1 at a time. Alternatively, the filter coefficient of the cutoff frequency ωc2 may be returned to the filter coefficient of the cutoff frequency ωc1 gradually or continuously.

Now, the description is returned to the block diagram of FIG. 2.

The digital amplifier 25 is a circuit that amplifies the output value (control value d8) of the digital low-pass filter 24 by a predetermined amplification factor, corrects the gain of the DCO 20, and outputs the generated control code (OTW) to the DCO 20.

The digital amplifier 25 further includes a holder 250 that holdes/unholdes the control code (OTW) to be output to the DCO 20 according to a predetermined instruction signal. In the intermittent operation control of the PLL loop, the control unit 104 outputs, to the digital amplifier 25, an instruction signal (a signal to hold the code) to open the PLL loop when the PLL loop is locked. The digital amplifier 25 temporarily holds, according to the input, the state of the control code (OTW) at the time and holds the output value to the DCO 20 side. Furthermore, the control unit 104 outputs, to the digital amplifier 25, an instruction signal (signal to unhold the code) to return the PLL loop when the PLL loop is returned. The digital amplifier 25 releases, according to the input, the holding state and outputs the control code (OTW) obtained from the output value of the digital low-pass filter 24.

The holder 250 of the digital amplifier 25 is configured with, for example, latch circuits (such as a gated D-latch circuit) of the number of bits of the control code (OTW) output in parallel.

In the case of the gated D-latch circuit, the instruction signal output from the control unit 104 to switch the intermittent operation of the PLL loop is input to an enable input terminal of the gated D-latch circuit. Furthermore, the bit signal of “1” or “0” indicating the control code (OTW) is input to a terminal D of the gated D-latch circuit, and the bit signal of “1” or “0” is output from a terminal Q. In this configuration, when the PLL loop is in a locked state, the control unit 104 inputs the instruction signal indicating ON to the enable input terminal. Then, the output from the terminal Q is held to the bit signal of “1” or “0” which is output when the enable input terminal is switched to ON. Thereafter, regardless of the input state of the terminal D, the output is held to the above bit signal, and the control code (OTW) based on the held bit signal is output to the DCO 20.

Note that, it is assumed that the control unit 104 inputs the instruction signal to the enable input terminal in the locked state of the PLL loop before the power supply to the digital low-pass filter 24 and the like is stopped.

Alternatively, when the PLL loop is returned, the control unit 104 inputs the instruction signal indicating OFF to the enable input terminal. In this case, the bit signal of “1” or “0” indicating the control code (OTW) to be input to the terminal D is output from the terminal Q. Therefore, the output signal of the terminal Q, which is held when the PLL loop is locked, is unheld.

Note that, it is assumed that the control unit 104 inputs the instruction signal to the enable input terminal when the PLL loop is returned after the power supply to the digital low-pass filter 24 is resumed.

The phase comparator (first detector) 26 inputs the phase difference information d7 output from the subtractor 23 and outputs, to the control unit 104, a signal d0 indicating the locked state of the PLL loop when the phase difference indicates 0 or the value within the tolerance range in the vicinity thereof.

To control the intermittent operation of the PLL loop, the control unit 104 includes a first timer C1, a determination unit C2, a power ON/OFF control unit C3, and a coefficient setting unit C4.

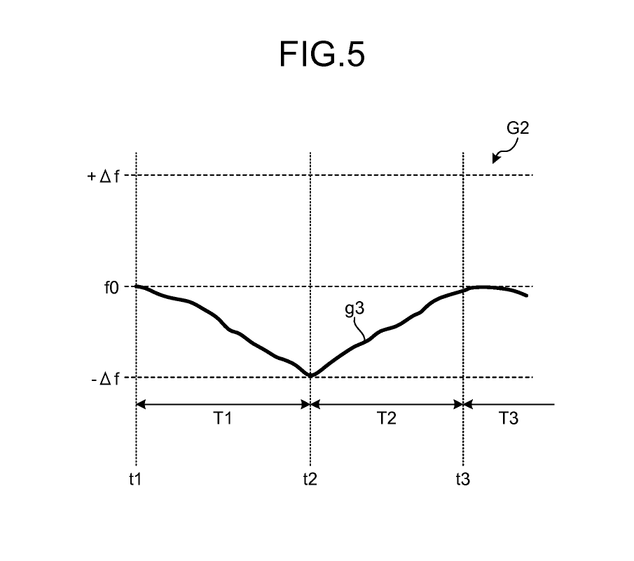

The first timer C1 clocks a predetermined returning time of the PLL loop. As the predetermined returning time of the PLL loop, for example, the estimated time calculated by measuring in advance the time until just before the oscillation frequency of the output signal of the DCO 20 deviates from a predetermined variation Δf (refer to FIG. 5) is used.

The determination unit C2 monitors the output from the phase comparator 26 and determines as the locked state of the PLL loop when the signal d0 is output from the phase comparator 26. Furthermore, the determination unit C2 monitors the first timer C1 and determines that the first timer C1 has clocked the predetermined returning time of the PLL loop.

The power ON/OFF control unit (switch control unit) C3 outputs a control signal e1 and performs switch control of an electronic switch, such as a Field Effect Transistor (FET), which turns on/off the power of the phase-to-digital converter 21, the accumulator 22, the subtractor 23, the digital low-pass filter 24, and the phase comparator 26. The power ON/OFF control unit turns on/off the power of the above parts by performing the switch control of the electronic switch and stops/resumes the signal input to the digital input/output units of the above parts.

Note that, as the above switch control unit, a unit other than the power ON/OFF control unit may be applicable. For example, in order for the above parts not to operate digitally, a unit for interrupting/resuming the transmission of a signal (for example, a data signal and a clock signal) may be provided. In this case, the signal input to the digital input/output units of the above parts can be stopped/resumed. In the following description, an example in which the power ON/OFF control unit is applied to the switch control unit will be described.

The coefficient setting unit C4 dynamically sets the filter coefficient of the digital low-pass filter 24.

The control unit 104 is connected to the modulator 101 illustrated in FIG. 1, the data processing unit (not illustrated) and the like with the control signal and the like.

Next, an operation flow of the control unit 104 at transmission will be described.

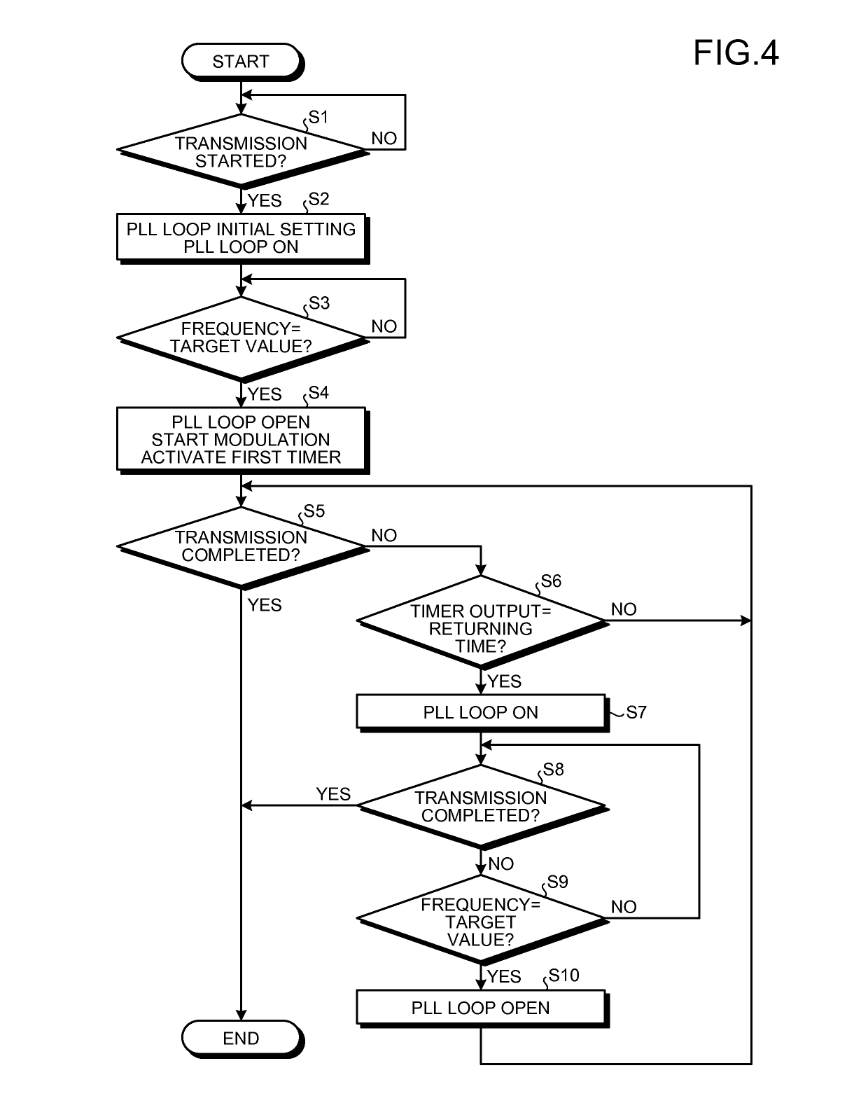

FIG. 4 is a diagram illustrating an example of the operation flow chart of the control unit 104 of the embodiment at transmission.

First, the control unit 104 detects whether or not the transmission has been started (S1). When there is neither transmission data in the data processing unit, such as a DSP, nor instruction to start the transmission, the control unit 104 repeats the processing of step S1 (step S1: No determination).

When there is transmission data in the data processing unit and the instruction to start the transmission, the control unit 104 detects the instruction to start the transmission in step S1 (Yes determination) and activates the ADPLL 100 (S2). In this activation, the control unit 104 performs the initial settings, such as the setting of the filter coefficient to the digital low-pass filter 24 of the ADPLL 100. The filter coefficient is set to the coefficient in the normal operation in which the PLL loop is closed (the filter coefficient corresponding to the cutoff frequency ωc1). Thereafter, the ADPLL 100 performs lock control of the PLL loop (PLL loop ON control) in order to adjust the oscillation frequency of the output signal of the DCO 20 to the set frequency (target value) of the FCW.

After the activation in step S2, the control unit 104 determines whether or not the oscillation frequency of the output signal of the DCO 20 matches the set frequency of the FCW (S3). In this determination, the control unit 104 monitors the output from the phase comparator 26, and when the output of the signal d0 from the phase comparator 26 is not detected (step S3: No determination), the control unit 104 repeats the determination of step S3 until the signal d0 is detected.

Here, it is assumed that the output of the signal d3 has been detected from the phase comparator 26 (step S3: Yes determination). Then, the control unit 104 performs control to open the PLL loop (PLL loop OPEN control) (S4).

In step S4, first, the control unit 104 outputs, to the digital amplifier 25, an instruction signal e2 to open the PLL loop. Thus, the control code (OTW) to be output from the digital amplifier 25 to the DCO 20 is held to a fixed value.

Next, the control unit 104 outputs the control signal e1 and switches the electronic switch to the off side. Thus, the control unit 104 stops the power supply to the phase-to-digital converter 21, the accumulator 22, the subtractor 23, the digital low-pass filter 24, and the phase comparator 26.

Furthermore, the control unit 104 activates a timer and starts to clock the retuning time of the PLL loop from 0.

Moreover, the control unit 104 instructs the modulator 101 to start the modulation of the transmission data. Thus, the modulation data is input from the modulator 101 to the ADPLL 100, and the output signal of the ADPLL 100 is modulated according to the modulation data. Thereafter, the output signal (the signal on which the data is superimposed) of the ADPLL 100 is power-amplified by the PA 102 and radiated from the antenna 103.

After the processing of step S4, the control unit 104 determines whether or not the transmission of the transmission data has been completed (S5).

When the transmission of all the transmission data has been completed and it is determined that the transmission has been completed in the determination of step S5 (Yes determination), the control unit 104 terminates the processing. That is, the control unit 104 stops the ADPLL 100.

When it is determined that the transmission has not been completed in the determination of step S5 (No determination), the control unit 104 determines whether or not the output value of the timer activated in step S4 reaches a predetermined returning time (S6).

When the output value of the timer is less than the returning time in the determination of step S6 (No determination), the control unit 104 performs the determination of step S5 again. Thereafter, the control unit 104 repeats the determination processing of step S5 and step S6, until it is determined as Yes in either of step S5 or step S6.

Here, in the determination of step S6, it is assumed that the control unit 104 determines that the output value of the timer has reached the predetermined returning time (Yes determination).

Then, the control unit 104 stops the timer and further performs the control to close the PLL loop (S7). In this control, the control unit 104 outputs the control signal e1 and switches the electronic switch to the on side. Thus, the control unit 104 resumes the power supply to the phase-to-digital converter 21, the accumulator 22, the subtractor 23, the digital low-pass filter 24, and the phase comparator 26. Furthermore, the control unit 104 sets, to the digital low-pass filter 24, the filter coefficient corresponding to the cutoff frequency ωc2. Then, the control unit 104 outputs, to the digital amplifier 25, the instruction signal e2 to close (return) the PLL loop. Thus, the control unit 104 unholds the control code (OTW) held at the digital amplifier 25 in step S4.

Next, the control unit 104 determines whether or not the transmission has been completed similarly to step S5 (S8).

When it is determined that the transmission has been completed in the determination of step S8 (Yes determination), the control unit 104 terminates the processing.

When it is determined that the transmission has not been completed in the determination of step S8 (No determination), the control unit 104 determines whether or not the oscillation frequency of the output signal of the DCO 20 matches the set frequency of the FCW (S9). The determination is performed by detecting the signal d0 output from the phase comparator 26 similarly to step S3. When the oscillation frequency does not match the set frequency (No determination), the determination of step S8 is performed again. Thereafter, the control unit 104 repeats the processing of step S8 and step 9, until it is determined as Yes in either of step S8 or step S9.

When it is determined that the oscillation frequency matches the set frequency in the determination of step S9 (Yes determination), the control unit 104 performs the control to open the PLL loop (S10).

In step S10, first, the control unit 104 outputs, to the digital amplifier 25, the instruction signal e2 to open the PLL loop. Thus, the control code (OTW) to be output from the digital amplifier 25 to the DCO 20 is held to a fixed value.

Next, the control unit 104 outputs the control signal e1 and switches the electronic switch to the off side. Thus, the control unit 104 stops the power supply to the phase-to-digital converter 21, the accumulator 22, the subtractor 23, the digital low-pass filter 24, and the phase comparator 26.

Furthermore, the control unit 104 activates a timer and starts to clock the retuning time of the PLL loop from 0.

After step S10, the control unit 104 similarly performs the control from step S5.

Thereafter, when the transmission of all the transmission data has been completed, and the control unit 104 determines that the transmission has been completed in step S5 or step S8 (Yes determination), the control unit 104 terminates the processing.

FIG. 5 is a diagram illustrating, with a graph, an example of a frequency change of the output signal of the DCO 20 of the embodiment when the PLL loop is returned.

In the graph G2, the abscissa indicates the elapsed time, and the ordinate indicates the frequency. The graph G2 illustrates the line graph g3 indicating that the frequency change in the intermittent operation of the PLL loop is plotted.

On the ordinate, f0 indicates the set frequency of the FCW. The frequency band of −Δf to +Δf indicates the permissive range of the frequency fluctuation from the set frequency f0 during which the PLL loop is opened.

On the abscissa, the T1 and T3 indicate the period during which the PLL loop is opened. The T2 indicates the period during which the PLL loop is closed (the period until the PLL is locked). The boundary between the T1 and T2 becomes the timing when the PLL loop is returned.

Note that, as the returning time set to the control unit 104, the time, from when the PLL loop is closed to when the oscillation frequency of the output signal of the DCO 20 deviates from the frequency band of −Δf to +Δf, is measured in advance. Then, the time during which the oscillation frequency stays in the frequency band of −Δf to +Δf is set as the returning time. In FIG. 5, the T1 or T3 is equivalent to the returning time.

Here, the locus of the frequency fluctuation illustrated as the line graph g3 in FIG. 5 will be described.

At the time when the PLL loop is opened (t1), the oscillation frequency of the output signal of the DCO 20 is the set frequency f0. Thereafter, the frequency gradually lowers or rises in various loci. In this example, the oscillation frequency, which gradually lowers and then lowers near −Δf just before the PLL loop is returned, is illustrated.

From the time when the PLL loop is returned (t2), the oscillation frequency is readjusted to the set frequency f0, and the oscillation frequency, which is smoothly returned to the set frequency f0, is illustrated in this example.

Thereafter, when the oscillation frequency reaches the set frequency f0, the PLL loop is opened again, and the oscillation frequency fluctuates within the frequency band of −Δf to +Δf until the next returning time T3 (the returning time is the same as the T1) elapses.

As described above, the line graph g3 indicates a smooth change at the time when the PLL loop is returned (t2). This is because the filter coefficient corresponding to the lower cutoff frequency ωc2 than the normal cutoff frequency ωc1 is set to the digital low-pass filter 24 when the PLL loop is returned.

In the next standard of the BLE “LE Data Length Extension”, a packet length becomes longer to a few milliseconds than that of the current standard. Therefore, when operating while the PLL loop is opened, the output frequency of the PLL circuit gradually fluctuates and the standard of the frequency deviation may not be satisfied. According to the present embodiment, the radio communication device repeats, until the transmission is completed, the PLL intermittent operation in which the PLL loop is opened when the oscillation frequency matches the set frequency of the FCW (the PLL loop is locked), and the PLL loop is closed (returned) when the timer clocks the predetermined returning time. Thus, it is possible to suppress the fluctuation of the output frequency of the PLL circuit within the standard of the frequency deviation. Furthermore, while the PLL loop is opened, the radio communication device can stop functions of a part of the PLL, and accordingly, it is possible to reduce the power consumption.

Furthermore, the radio communication device applies the lower cutoff frequency than that in the normal operation to the digital low-pass filter 24 when the PLL loop is returned. Thus, it is possible to smooth the frequency change of the output signal of the DCO just after the PLL loop is returned and to further stabilize the frequency. With this stabilization, it is possible to more reliably satisfy the standard of the frequency deviation in the next standard of BLE.

### Modified Example 1

In the embodiment, an aspect of the radio communication device, which determines according to the timer the timing to return (close) the PLL loop after the PLL loop is opened, has been described.

In a modified example 1, an aspect of a radio communication device, which determines the timing to return a PLL loop according to variation of an oscillation frequency of the output signal of a DCO 20, will be described.

Note that, in the following description, the similar description explained in the embodiment will be outlined or appropriately omitted. In the following description, the difference from the above embodiment will be mainly described.

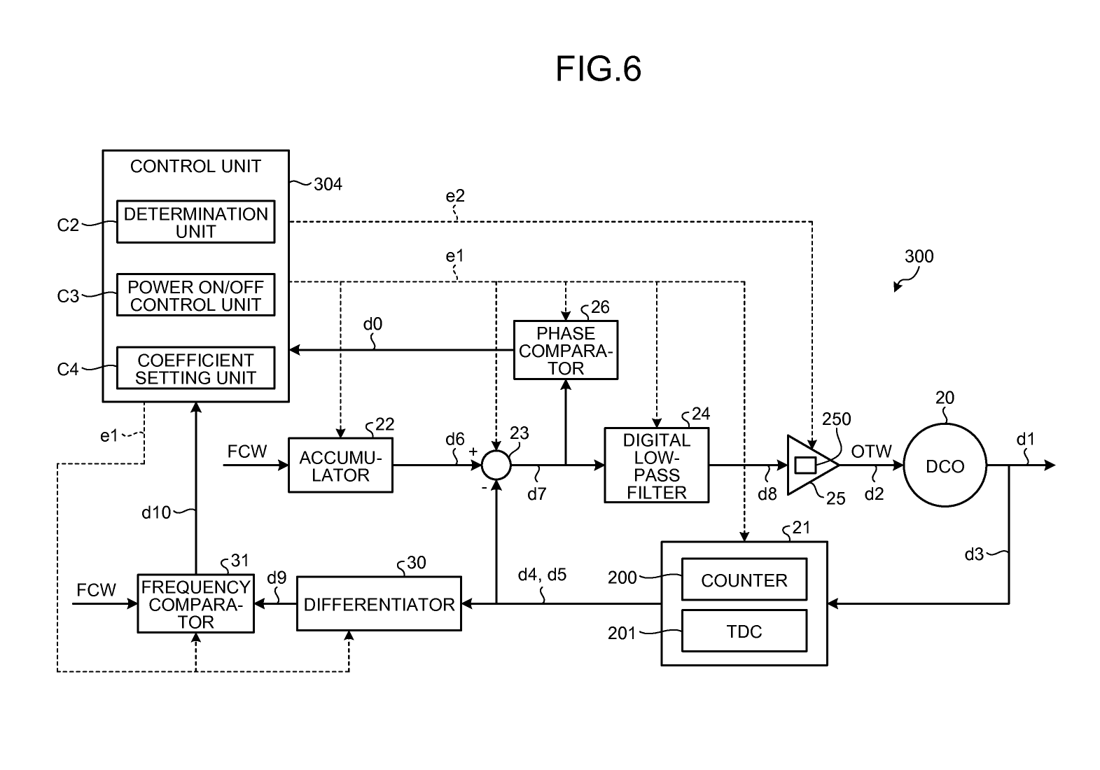

FIG. 6 is a block diagram of an ADPLL illustrated as an example of a modified example 1.

An ADPLL 300 of the modified example 1 further includes second detectors (a differentiator 30 and a frequency comparator 31) in addition to the ADPLL 100 according to the embodiment (refer to FIG. 2).

The differentiator 30 is a circuit that converts phase information into frequency information by differentiating time. The differentiator 30 inputs the output from a phase-to-digital converter 21, converts the phase information into the frequency information, and outputs converted frequency information d9 to the frequency comparator 31.

The frequency comparator 31 is a detection circuit that monitors the change (difference) of the frequency information from a set frequency and detects the timing to return the PLL loop. The frequency comparator 31 inputs the frequency information d9 output from the differentiator 30 and a FCW indicating the set frequency. The frequency comparator 31 calculates the difference amount between the input FCW and frequency information d9 and compares the difference amount with a predetermined value (threshold value). Then, the frequency comparator 31 outputs, to a control unit 304, a trigger signal d10 indicating the timing to return the PLL loop when the difference amount exceeds the threshold value. Note that, it is assumed that the threshold value takes a value up to Δf (refer to FIG. 5). Here, as an example, the threshold value takes the maximum value Δf.

The control unit 304 is configured without a first timer C1.

The control unit 304 detects the timing to return the PLL loop according to the input of the trigger signal d10 output from the frequency comparator 31 instead of the timer. When the trigger signal d10 is output from the frequency comparator 31, by using the signal as a trigger, the control unit 304 performs control to return (close) the PLL loop of the ADPLL 300.

Next, the operation of the control unit 304 at transmission will be described.

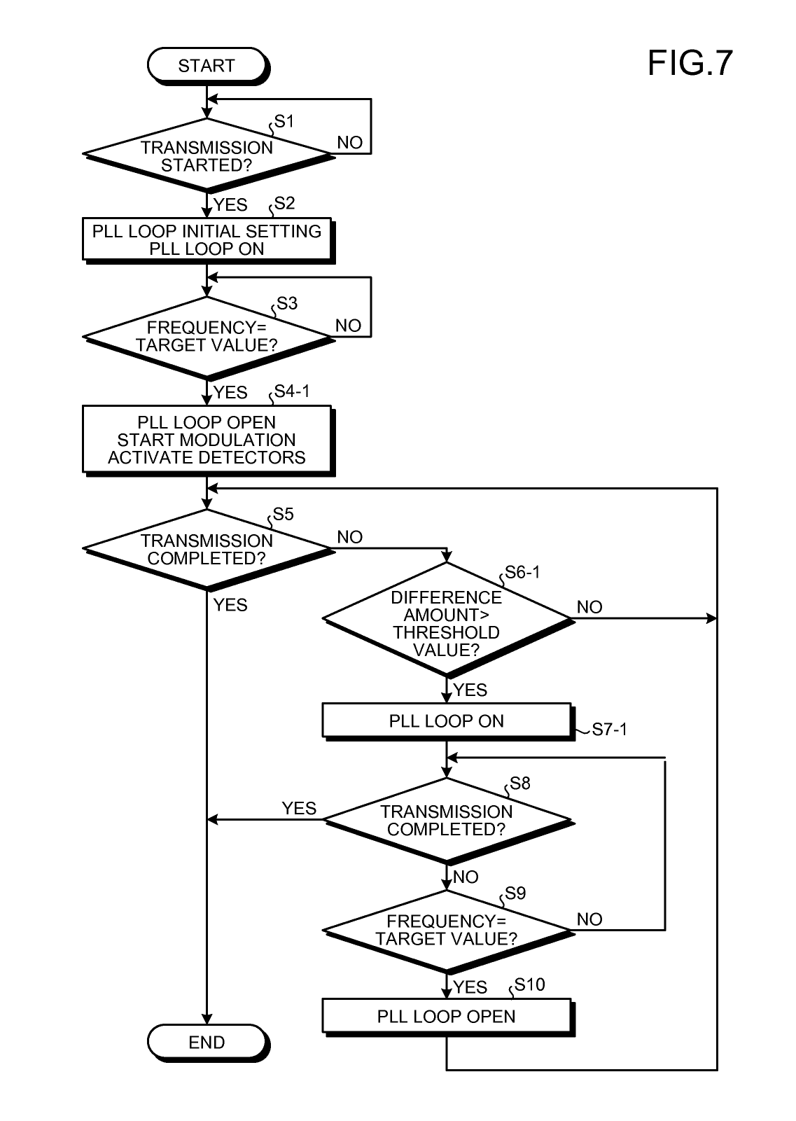

FIG. 7 is a diagram illustrating an example of the operation flow chart of the control unit 304 of the modified example 1 at transmission.

The processing by the control unit 304 illustrated in FIG. 7 overlaps with a part of the processing by the control unit 104 of the embodiment (refer to FIG. 4). Here, the same step number as FIG. 3 is assigned to the overlapped processing and the description thereof will be appropriately omitted.

First, the processing from steps S1 to S3 is similar to that by the control unit 104 of the embodiment. To be outlined, in steps S1 to S3, the ADPLL 300 is activated and performs lock control of the PLL loop (PLL loop ON control). The control unit 304 monitors the output from a phase comparator 26 and performs determination processing as to whether the oscillation frequency of the DCO 20 matches the set frequency of the FCW.

Here, it is assumed that the control unit 304 determines in step S3 that the oscillation frequency matches the set frequency of the FCW (Yes determination). Then, the control unit 304 performs control to open the PLL loop (PLL loop OPEN control) (S4-1).

In step S4-1, first, the control unit 304 outputs, to a digital amplifier 25, an instruction signal e2 to open the PLL loop. Thus, the control code (OTW) to be output from the digital amplifier 25 to the DCO 20 is held to a fixed value.

Next, the control unit 304 outputs a control signal e1 and switches the electronic switch to the off side. Thus, among the DCO 20, the phase-to-digital converter 21, an accumulator 22, a subtractor 23, a digital low-pass filter 24, the digital amplifier 25, the phase comparator 26 which are activated in ADPLL 300, the control unit 304 stops the power supply to the accumulator 22, the subtractor 23, the digital low-pass filter 24, and the phase comparator 26.

Furthermore, the control unit 304 activates the differentiator 30 and the frequency comparator 31. Thus, the control unit 304 detects the timing when the variation (difference amount) of the oscillation frequency of the DCO 20 exceeds the threshold value according to the trigger signal d10 output from the frequency comparator 31. More specifically, when the differentiator 30 and the frequency comparator 31 are activated, the phase information output from the phase-to-digital converter 21 is input to the differentiator 30, and the differentiator 30 converts the phase information into the frequency information. The frequency comparator 31 inputs the frequency information and the FCW and calculates the variation (difference amount) of the frequency information against the FCW. Furthermore, the frequency comparator 31 compares the difference amount with the threshold value set in advance and outputs the trigger signal d10 to the control unit 304 when the difference amount exceeds the threshold value.

Moreover, the control unit 304 instructs a modulator 101 (refer to FIG. 1) to start the modulation of the transmission data in step S4-1.

After step S4-1, the control unit 304 determines whether or not the transmission has been completed similarly to the processing by the control unit 104 of the embodiment (S5).

The control unit 304 detects the trigger signal d10 output from the frequency comparator 31, in the determination processing of step S6-1 after the No determination of step S5. In the determination processing of step S6-1, the control unit 304 determines whether or not the trigger signal d10 has been input from the frequency comparator 31.

When determining in step S6-1 that the signal has been input (Yes determination), the control unit 304 performs the control to close the PLL loop (S7-1).

In this control, the control unit 304 outputs the control signal e1 and switches the electronic switch to the on side. Thus, the control unit 304 resumes the power supply to the accumulator 22, the subtractor 23, the digital low-pass filter 24, and the phase comparator 26. Furthermore, the control unit 304 sets, to the digital low-pass filter 24, the filter coefficient corresponding to a cutoff frequency ωc2. The control unit 304 outputs, to the digital amplifier 25, the instruction signal e2 to close the PLL loop. Thus, the control unit 304 unholds the control code (OTW) held at the digital amplifier 25 in step S4-1.

On the other hand, when determining in step S6-1 that the signal has not been input (No determination), the control unit 304 returns to the processing of step S5.

The processing of steps S8 to S10 after the processing of step S7-1 has been described in the processing by the control unit 104 of the embodiment (refer to FIG. 4). To be outlined, the control unit 304 monitors the output from the phase comparator 26 after the PLL loop is closed and determines whether or not the oscillation frequency is returned to the set frequency of the FCW. When the oscillation frequency is returned to the set frequency of the FCW, the control unit 304 performs the control to open the PLL loop again.

In the modified example 1, the determination unit C2 of the control unit 304 monitors the output from the phase comparator 26 and performs the determination processing as to whether or not the oscillation frequency matches the set frequency in steps S3 and S9 illustrated in FIG. 7. However, the aspect of the determination processing is not limited to this. The frequency comparator 31 may be utilized for the determination processing of steps S3 and S9. In this case, it is assumed that the differentiator 30 and the frequency comparator 31 are started when the ADPLL 300 is activated.

For example, separately from the comparison between the difference amount of the frequency and the threshold value performed by the frequency comparator 31 in step S6-1, the frequency comparator 31 compares the difference amount with the value X (X=0 or the value equivalent to it). Furthermore, when the difference amount corresponds to the value X, the frequency detector 31 outputs, to the control unit 304, the trigger signal indicating the timing to open the PLL loop. The determination unit C2 of the control unit 304 monitors the output from the frequency comparator 31. Thus, when the frequency comparator 31 outputs the trigger signal indicating the timing to open the PLL loop, the control unit 304 detects the signal and performs the control to open the PLL loop in steps S4-1 and S10.

According to the modified example 1, the radio communication device monitors the output from the frequency comparator 31 while the PLL loop OPEN control is performed. Thus, the radio communication device detects, based on the output signal of the frequency comparator 31, that the oscillation frequency of the output signal of the DCO 20 is changed from the set frequency of the FCW by the predetermined amount (for example, Δf) and closes the PLL loop. Therefore, it is possible to follow the change of the oscillation frequency of the output signal of the DCO 20 and to more efficiently reduce the power consumption.

Furthermore, the frequency change of the output signal of the DCO 20 just after the PLL loop is closed is smooth as illustrated in FIG. 5, and it is possible to stabilize the frequency. With this stabilization, it is possible to more reliably satisfy the standard of the frequency deviation in the next standard of the BLE “LE Data Length Extension”.

### Modified Example 2

In the modified example 1, an aspect of the radio communication device, which activates the detectors (the differentiator 30 (refer to FIG. 6) and the frequency comparator 31 (refer to FIG. 6)) that detect the variation of the frequency and detects the timing to return the PLL loop according to the variation of the frequency, has been described.

In a modified example 2, an aspect of a radio communication device that operates the above detectors with a timer will be described.

Note that, in the modified example 2, a device, which compares an difference amount indicating the change of the frequency with the value X (X=0 or the value equivalent to it) and outputs, to the control unit 304 (refer to FIG. 6), a trigger signal to open a PLL loop when the difference amount corresponds to the value X, is applied to the frequency comparator 31.

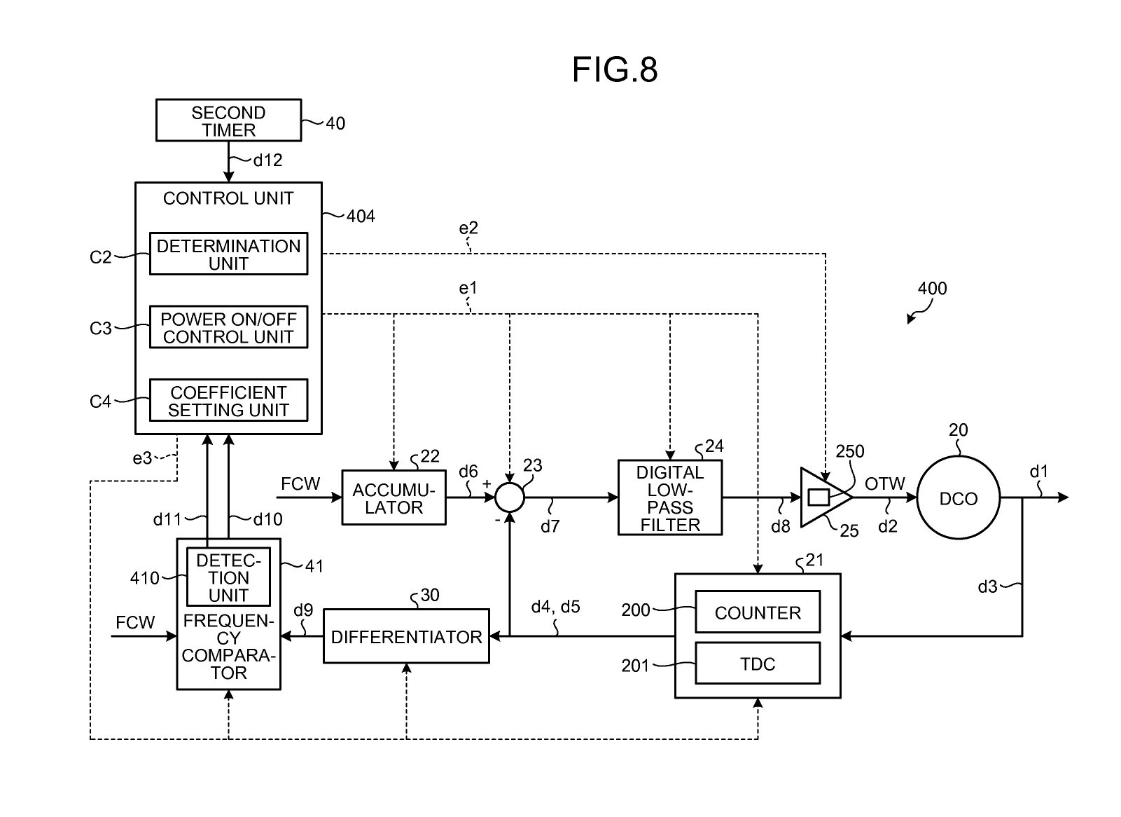

FIG. 8 is a block diagram of an ADPLL illustrated as an example of a modified example 2.

An ADPLL 400 of the modified example 2 further includes a second timer 40 in addition to the ADPLL 300 of the modified example 1 (refer to FIG. 6). The second timer 40 is configured with a counter and the like and clocks the switching time for the intermittent operation to activate or stop a detector and the like (that is, a phase-to-digital converter 21, a differentiator 30, and a frequency comparator 41). The second timer 40 outputs, to a control unit 404, a signal d12 indicating a timing every time a predetermined time elapses.

Furthermore, the configuration of the ADPLL 400 is similar to that of the ADPLL 300 of the modified example 1 except for the phase comparator 26. Instead of it, the ADPLL 400 includes a detection unit in the frequency comparator 31.

The frequency comparator 41 illustrated in FIG. 8 further includes a detection unit 410 that detects the timing when the oscillation frequency of the output signal of a DCO 20 matches the set frequency of a FCW in addition to the frequency comparator 31 of the modified example 2. More specifically, the detection unit 410 compares the difference amount between the set frequency of the FCW; and frequency information d9 which are calculated by the frequency comparator 41. Then, when the difference amount reaches the value X (X=0 or the value equivalent to it), the detection unit 410 outputs, to the control unit 404, a trigger signal d11 indicating a timing to open the PLL loop.

The control unit 404 monitors the output from the frequency comparator 41 and detects the timing to open the PLL loop according to the input of the trigger signal d11 output from the frequency comparator 41. By using this input as a trigger, the control unit 404 performs control to open the PLL loop of the ADPLL 400 (PLL OPEN control).

The control unit 404 detects the timing to return the PLL loop according to the input of a trigger signal d10 output from the frequency comparator 41 similarly to the modified example 1. By using this input as a trigger, the control unit 404 performs control to return the PLL loop of the ADPLL 400 (PLL loop ON control).

Furthermore, while the PLL loop is opened, the control unit 404 activates the second timer 40, monitors the output from the second timer 40, and detects the lapse of the predetermined time. Thus, while the PLL loop is opened, the control unit 404 performs, every time the predetermined time elapses, ON/OFF control of the power of the detector and the like (that is, the phase-to-digital converter 21, the differentiator 30, and the frequency comparator 41) through that the control unit 404 monitor the change of the oscillation frequency of the DCO 20. More specifically, the control unit 404 performs the switch control of ON/OFF of the power of the detector and the like by controlling the electronic switch of the FET and the like.

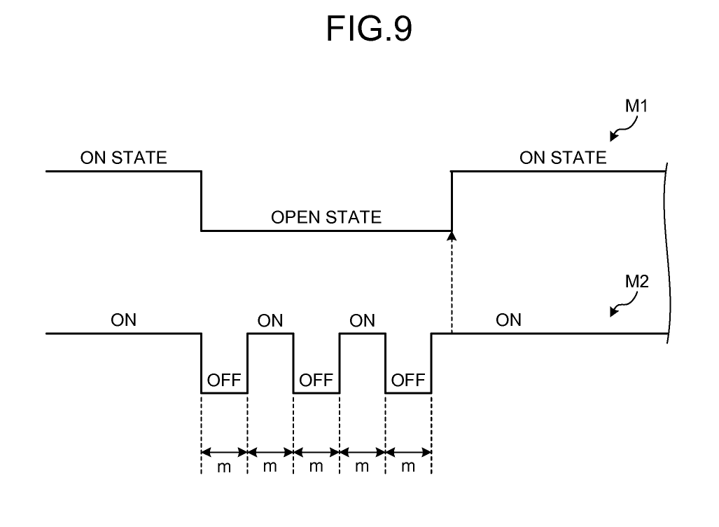

FIG. 9 is a timing chart illustrating an example of the ON/OFF control of the power of the detector and the like of the modified example 2.

The timing chart M1 of FIG. 9 indicates the timing of the intermittent operation of the PLL by the control unit 404.

The timing chart M2 of FIG. 9 indicates the timing of switching the power of the detector and the like by the control unit 404. This switching timing is based on the signal d12 output from the second timer 40 at a predetermined time interval.

In the timing chart M1, the Hight level state indicates that the PLL loop is closed (PLL loop ON state), and the Low level state indicates that the PLL loop is opened (PLL loop OPEN state).

In the timing chart M2, the Hight level state indicates the power ON state of the detector and the like, and the Low level state indicates the power OFF state of the detector and the like.

As illustrated in FIG. 9, the control unit 404 performs the control to power on the detector and the like in the PLL loop ON state. On the other hand, the control unit 404 performs the control to repeat the power ON and OFF of the detector and the like alternately in the PLL loop OPEN state.

In the present example, when switching the PLL loop from the ON state to the OPEN state, first, the control unit 404 switches the power of the detector and the like to OFF. Furthermore, the control unit 404 activates the second timer 40 and monitors the output from the second timer 40. When the second timer 40 outputs the signal d12 indicating the lapse of the predetermined time m, the control unit 404 performs the switch control of the power of the detector and the like to ON. Thereafter, the control unit 404 monitors the output from the second timer 40, and performs the switch control of the detector and the like to OFF when the second timer 40 outputs the signal indicating the lapse of the predetermined time m. This alternate switching operation is repeated until the control unit 404 returns the PLL loop from the OPEN state to the ON state. After returning the PLL loop to the ON state, the control unit 404 keeps the power of the detector and the like ON.

Note that, the time interval of the switch control (predetermined time m) may be appropriately determined. Furthermore, the periods during which the power of the detector and the like are ON and OFF may be different instead of being the same.

Next, the operation of the control unit 404 at transmission will be described.

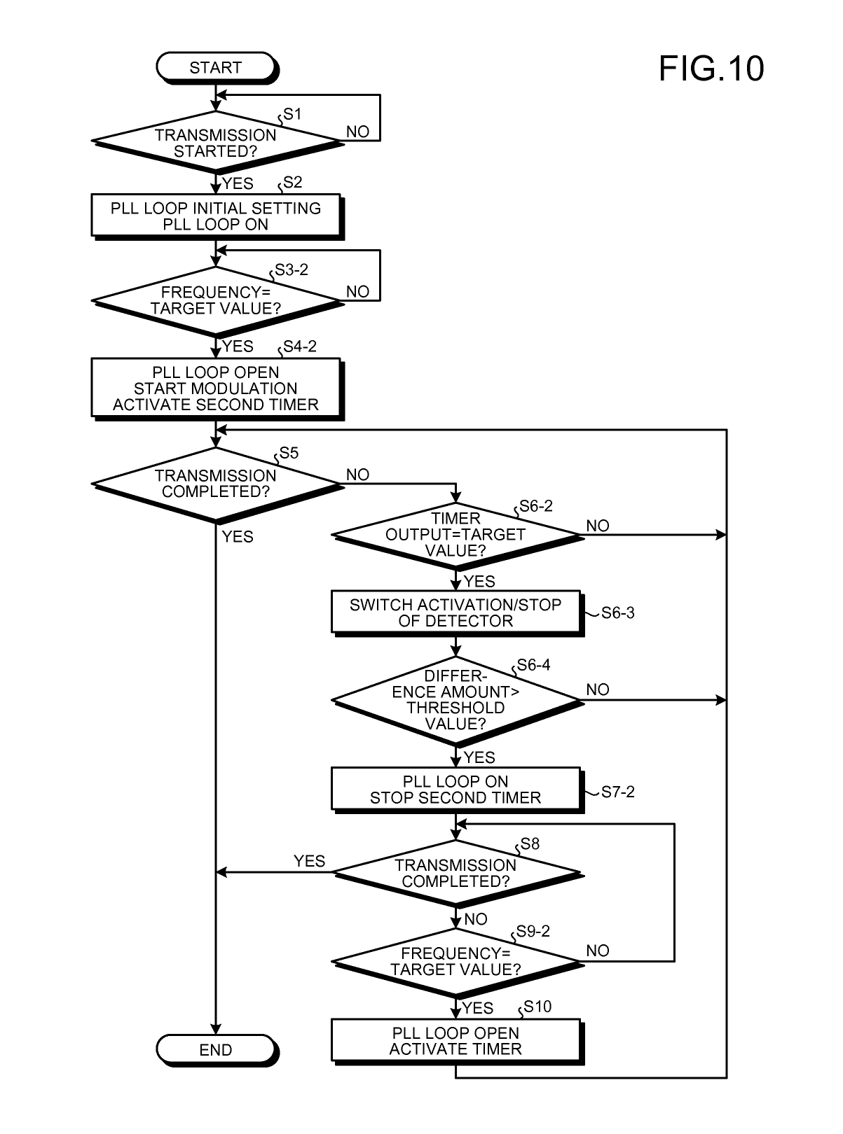

FIG. 10 is a diagram illustrating an example of an operation flow chart of the control unit 404 of the modified example 2 at transmission. The processing by the control unit 404 illustrated in FIG. 10 overlaps with a part of the processing by the control unit 304 of the modified example 1 (refer to FIG. 7). Here, the same step number as FIG. 7 is assigned to the overlapped processing and the description thereof will be appropriately omitted.

In steps S1 and S2, the control unit 404 performs the similar processing to the control unit 304 of the modified example 1. To be outlined, in steps S1 and S2, the control unit 404 detects the transmission start and activates the ADPLL 400. Thus, the ADPLL 400 starts lock control of the PLL loop (PLL loop ON control). Note that, in the modified example 2, it is assumed that the DCO 20, the phase-to-digital converter 21, an accumulator 22, a subtractor 23, a digital low-pass filter 24, the differentiator 30, and the frequency comparator 41 are activated by activating the ADPLL 400.

Next, the control unit 404 determines whether or not the oscillation frequency of the output signal of the DCO 20 matches the set frequency of the FCW (S3-2). The control unit 404 monitors the output from the frequency comparator 41, thus this determination is performed. When the trigger signal d11 is output from the frequency comparator 41, the control unit 404 determines that the oscillation frequency matches the set frequency of the FCW (Yes determination), and the processing proceeds to next step S4-2. When the trigger signal d11 is not output from the frequency comparator 41, the control unit 404 waits until the trigger signal d11 is output.

When it is determined as Yes in step S3-2, the control unit 404 performs control to open the PLL loop (PLL loop OPEN control) (S4-2).

In step S4-2, first, the control unit 404 outputs, to a digital amplifier 25, an instruction signal e2 to open the PLL loop. Thus, the control code (OTW) to be output from the digital amplifier 25 to the DCO 20 is held to a fixed value.

Next, the control unit 404 outputs control signals e1 and e3 and performs the control to switch the electronic switch to the off side. Thus, the control unit 404 stops the power supply to the phase-to-digital converter 21, the accumulator 22, the subtractor 23, the digital low-pass filter 24, the differentiator 30, and the frequency comparator 41.

Furthermore, the control unit 404 activates the second timer 40 and monitors the output from the second timer 40.

As described above, in the present example, the detector and the like are stopped just after the PLL loop is opened, and the control unit 404 monitors the output value of the second timer 40.

Furthermore, the control unit 404 instructs a modulator 101 to start the modulation of the transmission data in step S4-2.

Following to step S4-2, the control unit 404 determines whether or not the transmission has been completed similarly to the processing by the control unit 304 of the modified example 1 (refer to FIG. 7) (S5).

When it is determined as No in step S5, the control unit 404 determines whether or not the signal d12 has been output from the second timer 40 (S6-2). When the signal d12 has not been output (No determination), the control unit 404 returns to the determination processing of step S5 and repeats the processing.

When the signal d12 has been output from the second timer 40 (step S6-2: Yes determination), the control unit 404 switches the activation/stop of the detector and the like (S6-3). Here, the control unit 404 performs the control to switch the electronic switch of the detector and the like (the phase-to-digital converter 21, the differentiator 30, and the frequency comparator 41) from OFF to ON. Thus, the control unit 404 resumes the power supply to the detector and the like.

Next, the control unit 404 monitors the trigger signal d10 output from the frequency comparator 41 by activating the detector and the like and determines whether or not the variation of the oscillation frequency of the DCO 20 has exceeded the threshold value (S6-4).

More specifically, when the phase-to-digital converter 21, the differentiator 30, and the frequency comparator 41 are activated, phase information output from the phase-to-digital converter 21 is input to the differentiator 30, and the differentiator 30 converts the phase information into the frequency information. The frequency comparator 41 inputs the frequency information and the FCW and calculates the variation (difference amount) of the frequency information against the FCW. Furthermore, the frequency comparator 41 compares the difference amount and the threshold value (for example, Δf) set in advance and determines whether or not the difference amount has exceeded the threshold value. Then, when the difference amount exceeds the threshold value, the frequency comparator 41 outputs, to the control unit 404, the trigger signal d10. The control unit 404 monitors the output from the frequency comparator 41, and determines that the variation of the oscillation frequency of the output signal of the DCO 20 has exceeded the threshold value (step S6-4: Yes determination) when the trigger signal d10 is output.

When it is determined as No in step S6-4, the control unit 404 repeats the processing from step S5. Here, it is assumed that the signal d12 is output from the second timer 40 again in step S6-2 following step S5 (step S6-2: Yes determination). Then, in the following step S6-3, the control unit 404 performs the control to switch the electronic switch of the detector and the like from ON to OFF this time. Thus, the control unit 404 stops the power supply to the detector and the like.

Since the frequency comparator 41 is stopped and the control unit 404 does not detect the output of the trigger signal d10, it is determined as No in the following step S6-4. Thus, the control unit 404 repeats the processing from step S5 again.

While the detector and the like are activated, when the control unit 404 detects the trigger signal d10 from the frequency comparator 41, it is determined as Yes in step S6-4.

When it is determined as Yes in step S6-4, the control unit 404 performs the control to close the PLL loop (S7-2). In this control, the control unit 404 outputs the control signal e1 and switches the electronic switch to the on side. Thus, the control unit 404 resumes the power supply to the accumulator 22, the subtractor 23, and the digital low-pass filter 24. Furthermore, the control unit 404 sets, to the digital low-pass filter 24, the filter coefficient corresponding to a cutoff frequency ωc2. Moreover, the control unit 404 outputs, to the digital amplifier 25, the instruction signal e2 to close the PLL loop. Thus, the control unit 404 unholds the control code (OTW) held at the digital amplifier 25 in step S4-2. Furthermore, the control unit 404 stops the second timer 40.

Thereafter, the control unit 404 performs the determination processing as to whether or not the transmission has been completed (S8).

When it is determined as No in step S8, the control unit 404 determines whether or not the oscillation frequency of the output signal of the DCO 20 is returned to the set frequency of the FCW (S9-2). The control unit 404 monitors the output of the trigger signal d11 from the frequency comparator 41, thus this determination is performed similarly to step S3-2. When the trigger signal d11 has not been detected (No determination), the determination of step S8 is performed again. Thereafter, the control unit 404 repeats steps S8 to S9-2, until it is determined as Yes in either of step S8 or step S9-2.

In step S9-2, when the trigger signal d11 has been detected (Yes determination), the control unit 404 performs the control to open the PLL loop again (S10).

In step S10, first, the control unit 404 outputs, to the digital amplifier 25, the instruction signal e2 to open the PLL loop. Thus, the control code (OTW) to be output from the digital amplifier 25 to the DCO 20 is held to a fixed value.

Next, the control unit 404 outputs control signals e1 and e3 and performs the control to switch the electronic switch to the off side. Thus, the control unit 404 stops the power supply to the phase-to-digital converter 21, the accumulator 22, the subtractor 23, the digital low-pass filter 24, the differentiator 30, and the frequency comparator 41.

Furthermore, the control unit 404 activates the second timer 40 and monitors the output from the second timer 40.

After the PLL loop is opened, the control unit 404 similarly repeats the processing from step S5. Further repeated description will be omitted.

According to the modified example 2, while the PLL is opened, the radio communication device monitors the timing at the predetermined time interval with the second timer 40 and performs, at the timing of the predetermined time interval, the control to switch the power of the detector and the like (the phase-to-digital converter 21, the differentiator 30, and the frequency comparator 41) from ON to OFF or from OFF to ON alternately. Thus, while the PLL loop is opened, the detector and the like intermittently operate, and it is possible to reduce the power consumption of the detector and the like.

Furthermore, the frequency change of the output signal of the DCO 20 just after the PLL loop is closed is smooth as illustrated in FIG. 5, and it is possible to stabilize the frequency. With this stabilization, it is possible to more reliably satisfy the standard of the frequency deviation in the next standard of the BLE “LE Data Length Extension”.

### Modified Example 3

In the modified example 1, an aspect of the radio communication device, which activates the detector and the like (the phase-to-digital converter 21, the differentiator 30, and the frequency comparator 41) that detect the variation of the frequency and detects the timing to return the PLL loop according to the variation of the frequency, has been described.

In the modified example 3, an aspect of a radio communication device, which includes a detector that detects the variation of the frequency and a detector that detects the variation of the phase, uses them selectively, and detects the timing to return a PLL loop, will be described.

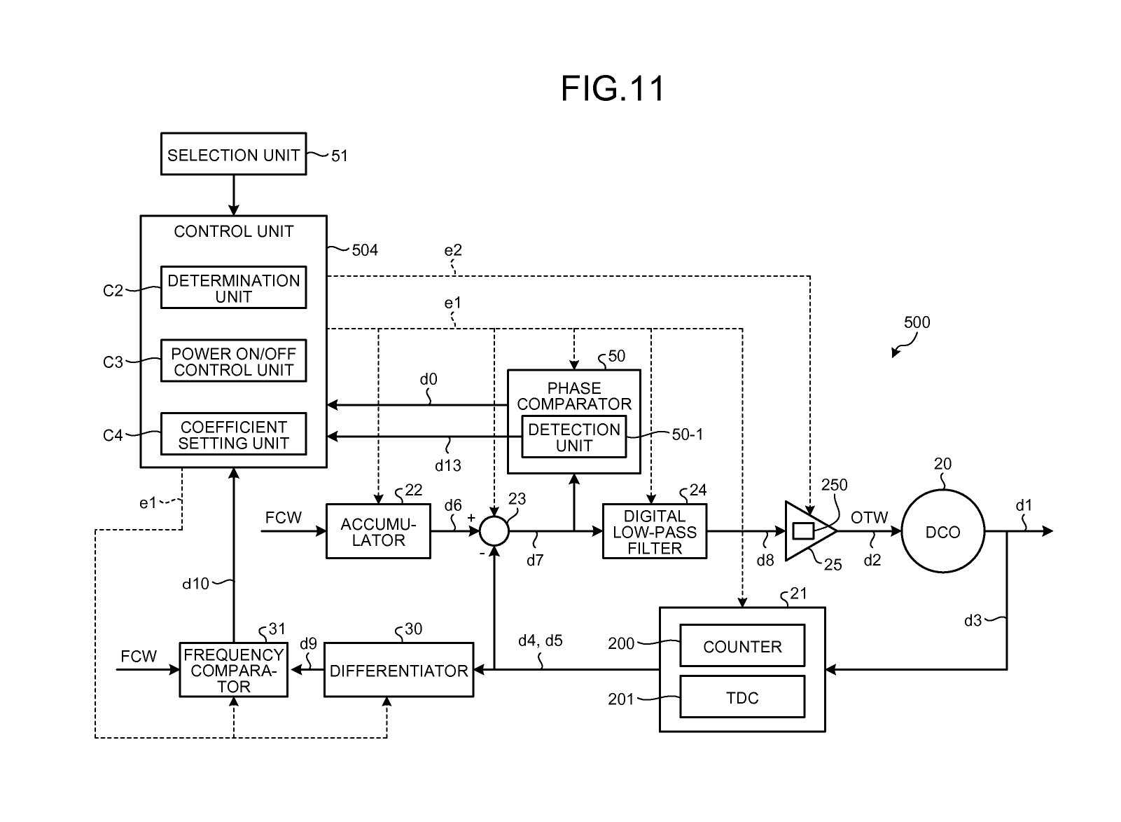

FIG. 11 is a block diagram of an ADPLL illustrated as an example of a modified example 3; and

An ADPLL 500 of the modified example 3 replaces the phase comparator 26 with a phase comparator 50 and further includes a selection unit 51 in addition to the ADPLL 300 of the modified example 1 (refer to FIG. 6).

The phase comparator 50 further includes a detection unit 50-1 that detects the variation of the phase after the PLL loop is opened, in addition to the phase comparator 26. The detection unit 50-1 inputs phase difference information d7 output from a subtractor 23, and outputs, to a control unit 504, a trigger signal d13 indicating that the phase shift occurs in the output signal of a DCO 20 when the phase difference information d7 exceeds a predetermined threshold value. In the present example, since the phase difference information d7 just after the PLL loop is opened is the value Y (Y=0 or the value equivalent to it), the threshold value takes the value Y.

The selection unit 51 is a unit for a user to selectively designate, to the control unit 504, either of the frequency shift detector (second detector) or the phase shift detector (the phase comparator 50 as the first detector) to detect the timing to return the PLL loop (the timing to start the PLL loop ON control). The selection unit 51 is configured with a switch, for example, a toggle switch or a DIP switch. The user switches the switch to the “frequency shift” side, and thus the control unit 504 performs power control, which will be described later, and detects the timing to return the PLL loop according to a trigger signal d10 output from a frequency comparator 31. Furthermore, when the user switches the switch to the “phase shift” side, the control unit 504 performs the power control, which will be described later, and detects the timing to return the PLL loop according to the trigger signal d13 output from the phase comparator 50.

The control unit 504 has the substantially same configuration as the control unit 304 of the modified example 1. The main difference is that the control unit 504 switches, according to the switching of the selection unit 51, either of the phase comparator 50 or the frequency comparator 31 to monitor the signal indicating the timing to return the PLL loop.

With the above configuration, the control unit 504 detects the timing to return the PLL loop by monitoring the output signal according to the “frequency shift” or the “phase shift” designated by the selection unit 51.

The ON/OFF control of the power of the ADPLL 500 is performed as follows.

When the “frequency shift” is selected, while the PLL loop is closed, the detectors (a differentiator 30 and the frequency comparator 31) that detect the variation of the frequency are powered OFF. While the PLL loop is opened, the above detectors are powered ON, and an accumulator 22, a subtractor 23, a digital low-pass filter 24, and the phase comparator 50 are powered OFF.

When the “phase shift” is selected, the detectors (the differentiator 30 and the frequency comparator 31) that detect the variation of the frequency are powered OFF continuously. While the PLL loop is opened, the digital low-pass filter 24 is further powered OFF.

Next, the operation of the control unit 504 at transmission will be described.

Since the operation flow of the control unit 504 at transmission when the “frequency shift” is selected can be described similarly to the processing of the control unit 304 of the modified example 1 (refer to FIG. 7), the description thereof will be omitted here.

Next, the operation flow of the control unit 504 at transmission when the “phase shift” is selected will be described.

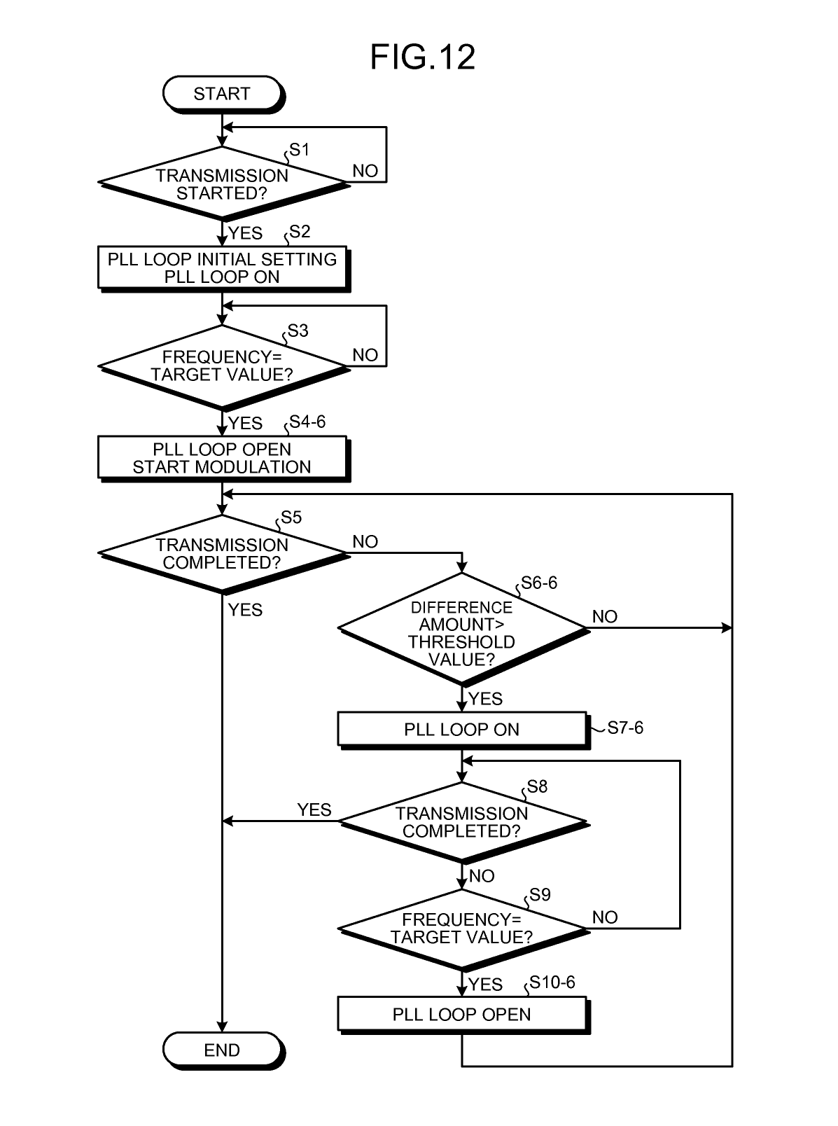

FIG. 12 is a diagram illustrating an example of the operation flow of the control unit 504 of the modified example 3 at transmission when the phase shift is selected.

The processing illustrated in FIG. 12 overlaps with a part of the processing illustrated in FIG. 7. The same step number as FIG. 7 is assigned to the overlapped processing.

In the processing illustrated in FIG. 12, the processing different from that illustrated in FIG. 7 is mainly the processing of steps S4-6, S6-6, S7-6, and S10-6.

In the following description, the overlapped description will be omitted, and the different processing will be described in order.

In step S4-6, the control unit 504 performs control to open the PLL loop (PLL loop OPEN control).

In step S4-6, first, the control unit 504 outputs, to a digital amplifier 25, an instruction signal e2 to open the PLL loop. Thus, a control code (OTW) output from the digital amplifier 25 to the DCO 20 is held.

Next, the control unit 504 outputs a control signal e1 and switches the electronic switch to the off side. Thus, among the DCO 20, a phase-to-digital converter 21, the accumulator 22, the subtractor 23, the digital low-pass filter 24, the digital amplifier 25, and the phase comparator 50 which are activated in the ADPLL 500, the control unit 504 stops the power supply to the digital low-pass filter 24.

Thereafter, the control unit 504 monitors the output from the phase comparator 50 and detects the timing when the phase difference of the output signal of the DCO 20 exceeds the threshold value (Y) according to the trigger signal d13 output from the phase comparator 50.

In addition, in step S4-6, the control unit 504 instructs a modulator 101 to start the modulation of the transmission data.

In step S6-6, the control unit 504 monitors the output from the phase comparator 50 and determines whether or not the trigger signal d13 has been output. When the trigger signal d13 has been output, it is determined as Yes.

In step S7-6, the control unit 504 performs the control to close the PLL loop.

In this control, the control unit 504 outputs the control signal e1 and switches the electronic switch to the on side. Thus, the control unit 504 resumes the power supply to the digital low-pass filter 24. Furthermore, the control unit 504 sets, to the digital low-pass filter 24, the filter coefficient corresponding to a cutoff frequency ωc2. Moreover, the control unit 504 outputs, to the digital amplifier 25, the instruction signal e2 to close the PLL loop. Thus, the control unit 504 unholds the control code (OTW) held at the digital amplifier 25 in step S4-6.

In step S10-6, the control unit 504 performs control to open the PLL loop (PLL loop OPEN control).

In step S10-6, first, the control unit 504 outputs, to the digital amplifier 25, the instruction signal e2 to open the PLL loop. Thus, a control code (OTW) output from the digital amplifier 25 to the DCO 20 is held.

Next, the control unit 504 outputs a control signal e1 and switches the electronic switch to the off side. Thus, among the DCO 20, a phase-to-digital converter 21, the accumulator 22, the subtractor 23, the digital low-pass filter 24, the digital amplifier 25, and the phase comparator 50 which are activated in the ADPLL 500, the control unit 504 stops the power supply to the digital low-pass filter 24.

Thereafter, the control unit 504 monitors the output from the phase comparator 50 and detects the timing when the phase difference of the output signal of the DCO 20 exceeds the threshold value (Y) according to the trigger signal d13 output from the phase comparator 50.

In the radio communication device of the modified example 3, in the control using the “frequency shift”, when the phase difference between the output signal of the DCO 20 and the FCW reaches 0 or the value within the tolerance range in the vicinity thereof, the PLL operates in the OPEN mode, and when the variation of the oscillation frequency of the output signal of the DCO 20 is changed from the set frequency of the FCW by the predetermined amount (for example, Δf), the PLL loop is returned. This intermittent operation of the PLL loop is repeated until the transmission is completed. Furthermore, the frequency change of the output signal of the DCO 20 just after the PLL loop is returned is smooth as illustrated in FIG. 5.

On the other hand, in the control using the “phase shift”, when the phase difference between the output signal of the DCO 20 and the FCW reaches 0 or the value within the tolerance range in the vicinity thereof, the PLL operates in the OPEN mode, and when the above phase difference deviates from 0 or the value within the tolerance range in the vicinity thereof, the PLL loop is returned. This intermittent operation of the PLL loop is repeated until the transmission is completed. Furthermore, the frequency change of the output signal of the DCO 20 just after the PLL loop is returned is smooth as illustrated in FIG. 5.

The user selects the above “phase shift” when the accuracy to match phases is required. In this case, while the PLL loop operates in the OPEN mode, the digital low-pass filter 24 is powered off, and it is possible to reduce the power consumption.

Furthermore, the user selects the above “frequency shift” when the accuracy to match phases is not required. In this case, while the PLL loop operates in the OPEN mode, the accumulator 22, the subtractor 23, the digital low-pass filter 24, and the like are powered OFF, and it is possible to largely reduce the power consumption. Furthermore, the time for the PLL loop to be returned is longer than that of the “phase shift”, and it is possible to enhance the power consumption effect during the time.

In the control of “frequency shift” of the modified example 3, the phase comparator 50 detects the frequency lock, and then the PLL operates in the OPEN mode. However, the method is not limited to this, the differentiator and the frequency comparator as described in the modified example 2 may detect the frequency lock. In this case, the phase comparator 50 can be stopped continuously.

Furthermore, by combining the second timer 40 described in the modified example 2 with the configuration described in the modified example 3, the differentiator 30 or the frequency comparator 31 may intermittently operate while the PLL operates in the OPEN mode. In this case, it is possible to reduce the power consumption of the differentiator 30 or the frequency comparator 31 while the PLL operates in the OPEN mode.

As described above, with the radio communication device of the embodiment and the modified examples, it is possible to achieve both reduction of the power consumption and stabilization of the frequency by utilizing the OPEN mode.

While certain embodiments have been described, these embodiments have been presented by way of example only, and are not intended to limit the scope of the inventions. Indeed, the novel radio communication devices and PLL loop control methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A radio communication device comprising:
a phase-locked loop (PLL) circuit that adjusts, based on control data, a frequency of an output signal to a target value;
a holder that temporarily holds, when a hold instruction signal to hold the control data is input, a state of the control data, and releases, when an unhold instruction signal to unhold the control data is input, a holding state of the control data; and
a control unit that outputs the hold instruction signal in a PLL lock state in which the frequency of the output signal reaches the target value, and outputs the unhold instruction signal after the hold instruction signal is output and before the frequency of the output signal deviates from the target value or a vicinity of the target value.

2. The radio communication device according to claim 1, wherein the control unit stops signal input to a part of a digital input/output unit of the PLL circuit after the hold instruction signal is input and until the unhold instruction signal is input.

3. The radio communication device according to claim 1, further comprising:
a digital low-pass filter that filters a high frequency component in a process of generating the control data; and
a coefficient setting unit that sets a filter coefficient of the digital low-pass filter, wherein
the coefficient setting unit resets a set value of the filter coefficient to a value indicating a lower value of a cutoff frequency before the unhold instruction signal is output.

4. The radio communication device according to claim 1, wherein the PLL circuit is an all digital phase-locked loop (ADPLL) circuit.

5. A radio communication device comprising:
a digitally controlled oscillator that adjusts, based on control data, a frequency of an output signal;
a phase-to-digital converter that converts a feedback signal, which is the fed-back output signal of the digitally controlled oscillator, into first phase data and outputs the first phase data;
an integrator that integrates frequency setting data and outputs second phase data;
a subtractor that generates phase difference data obtained by subtracting the first phase data from the second phase data;
a digital low-pass filter that filters the phase difference data and outputs basic control data;
a digital amplifier that generates the control data from the basic control data, outputs the generated control data to the digitally controlled oscillator, and outputs, when a hold instruction signal to hold the control data is input, the control data without changing a value until an unhold instruction signal to unhold the hold instruction is input;
a first detector that detects, based on the feedback signal, a PLL lock state in which the frequency of the output signal of the digitally controlled oscillator is a target value indicated in the frequency setting data;
a first timer that clocks an estimated time until just before the frequency of the output signal of the digitally controlled oscillator deviates from the target value or a vicinity of the target value;
a switch control unit that stops or resumes signal input to at least one digital input/output unit by a prior stage of the digital amplifier on a transmission path through which the frequency setting data or the feedback signal of the digitally controlled oscillator is transmitted; and
a control unit that performs PLL loop OPEN control in which the control unit outputs the hold instruction signal to the digital amplifier and further stops the signal input to the digital input/output unit by the switch control unit when the first detector detects the PLL lock state, and performs PLL loop ON control in which the control unit resumes the stopped signal input by the switch control unit and further outputs the unhold instruction signal to the digital amplifier when the first timer completes clocking the estimated time.

6. The radio communication device according to claim 5, wherein the digital input/output unit is the phase-to-digital converter, the integrator, the subtractor, the digital low-pass filter, or the first detector.

7. The radio communication device according to claim 5 further comprising:
a coefficient setting unit that sets a coefficient of the digital low-pass filter, wherein
the coefficient setting unit sets, to a coefficient of the digital low-pass filter, a coefficient indicating a lower value of a cutoff frequency before the unhold instruction signal is output to the digital amplifier.

8. The radio communication device according to claim 5 further comprising:
a second detector, replaced with the first timer, that calculates variation of a frequency indicated in the feedback signal from a set frequency indicated in the frequency setting data and detects a timing when the frequency of the output signal of the digitally controlled oscillator deviates from the target value or the vicinity of the target value, wherein
when the first detector detects the PLL lock state, the control unit performs PLL loop OPEN control in which the control unit outputs, to the digital amplifier, the hold instruction signal and further stops the signal input to at least one of the integrator, the subtractor, the digital low-pass filter, or the first detector by the switch control unit, and
when the second detector detects a timing when a frequency deviates from the target value or the vicinity of the target value, the control unit performs PLL loop ON control in which the control unit resumes the stopped signal input by the switch control unit and further outputs the unhold instruction signal to the digital amplifier.

9. The radio communication device according to claim 8, wherein when the first detector detects the PLL lock state, the control unit activates, as the second detector, a differentiator that converts phase information output by the phase-to-digital converter into frequency data and a frequency comparator that compares frequency data output by the differentiator with the frequency setting data.

10. The radio communication device according to claim 8 further comprising:
a coefficient setting unit that sets a coefficient of the digital low-pass filter, wherein
the coefficient setting unit sets a coefficient of the digital low-pass filter to a coefficient indicating a lower value of a cutoff frequency before the unhold instruction signal is output to the digital amplifier.

11. The radio communication device according to claim 8 further comprising:
a second timer that clocks a switching time in order for the second detector to perform intermittent operation until the frequency of the output signal of the digitally controlled oscillator deviates from the target value or the vicinity of the target value, wherein
when the first detector detects the PLL lock state, the control unit further performs, based on the switching time clocked by the second timer, PLL loop OPEN control in which the control unit stops and resumes alternately the signal input of the second detector by the switch control unit, until the frequency of the output signal of the digitally controlled oscillator deviates from the target value or the vicinity of the target value.

12. The radio communication device according to claim 11, wherein the second detector is the phase-to-digital converter, a differentiator that converts phase information output by the phase-to-digital converter into frequency data, or a frequency comparator that compares frequency data output by the differentiator with the frequency setting data.

13. The radio communication device according to claim 11, wherein the second detector further detects, instead of the first detector, the PLL lock state based on the feedback signal.

14. The radio communication device according to claim 11 further comprising:
a coefficient setting unit that sets a coefficient of the digital low-pass filter, wherein
the coefficient setting unit sets, to a coefficient of the digital low-pass filter, a coefficient indicating a lower value of a cutoff frequency before the unhold instruction signal is output to the digital amplifier.

15. The radio communication device according to claim 8 further comprising:
a phase comparator, as the first detector, that detects, based on phase difference data after subtraction by the subtractor, the PLL lock state and a timing when a phase shift occurs in the output signal of the digitally controlled oscillator; and
a selection unit that selects a detector that detects a timing to start the PLL loop ON control from a phase comparator as the first detector and the second detector, wherein
the control unit switches, according to selection of the selection unit, a control target to stop and resume the signal input by the switch control unit.

16. The radio communication device according to claim 11, wherein when the phase comparator is selected by the selection unit, the control unit continuously powers OFF the second detector.

17. The radio communication device according to claim 16, wherein the second detector is a differentiator that converts phase information output by the phase-to-digital converter to frequency data, or a frequency comparator that compares frequency data output by the differentiator with the frequency setting data.

18. The radio communication device according to claim 15, wherein
when the PLL lock state is detected while the second detector is selected by the selection unit, the control unit performs PLL loop OPEN control in which the control unit outputs, to the digital amplifier, the hold instruction signal and further stops the signal input to the phase comparator by the switch control unit, and
when the second detector detects a timing when a frequency deviates from the target value or the vicinity of the target value, the control unit performs PLL loop ON control in which the control unit resumes the stopped signal input by the switch control unit and further outputs the unhold instruction signal to the digital amplifier.

19. The radio communication device according to claim 15 further comprising:
a coefficient setting unit that sets a coefficient of the digital low-pass filter, wherein
the coefficient setting unit sets a coefficient of the digital low-pass filter to a coefficient indicating a lower value of a cutoff frequency before the unhold instruction signal is output to the digital amplifier.

20. A PLL loop control method comprising:
setting, to a coefficient of a digital low-pass filter of a PLL circuit, a value corresponding to a cutoff frequency in a normal operation;
detecting a PLL lock state while the value corresponding to the cutoff frequency in the normal operation is set;
performing PLL loop OPEN control in which the control unit holds a frequency of an output signal of the PLL circuit and further stops signal input to at least one digital signal input unit in the PLL circuit based on the detection of the PLL lock state;
detecting a timing when the frequency of the output signal deviates from a target value or a vicinity of the target value; and
performing PLL loop ON control in which the control unit resumes the signal input to the digital signal input unit, sets, to a coefficient of the digital low-pass filter, a value corresponding to a lower cutoff frequency than a cutoff frequency in the normal operation, and unholds the frequency of the output signal at a timing when the frequency of the output signal deviates from the target value or the vicinity of the target value.
